(19) United States
(12) Patent Application Publication
(10) Pub. No.: US 2024/0113062 A1
(43) Pub. Date: Apr. 4, 2024

(54) ASSEMBLY OF AN INTEGRATED CIRCUIT IN A CHIP SCALE BALL GRID ARRAY

(71) Applicant: Azimuth Industrial Company, Inc., Union City, CA (US)

(72) Inventor: David Lee, Palo Alto, CA (US)

(73) Assignee: Azimuth Industrial Company, Inc., Union City, CA (US)

(21) Appl. No.: 18/478,823

(22) Filed: Sep. 29, 2023

Related U.S. Application Data
(60) Provisional application No. 63/412,322, filed on Sep. 30, 2022.

(51) Int. Cl. H01L 23/00; H01L 21/56

(52) U.S. Cl. CPC H01L 24/20; H01L 21/56; H01L 24/19; H01L 23/3128; H01L 2224/19; H01L 2224/214; H01L 2224/215; H01L 2924/01029; H01L 2924/01047; H01L 2924/01079

(57) ABSTRACT

Implementations generally relate to an assembly of an integrated circuit in a chip scale ball grid array. In some implementations, an assembly includes an integrated circuit (IC) chip having wire bond pads. The assembly further includes ball bumps coupled to the wire bond pads of the IC chip. The assembly further includes an overmold that encapsulates the IC chip. The assembly further includes ball contact pads coupled to the overmold, wherein the ball contact pads are electrically coupled to the wire bond pads by way of the ball bumps. The assembly further includes solder balls coupled to the ball contact pads.

### CROSS REFERENCE TO RELATED APPLICATIONS

This application claims priority from U.S. Provisional Patent Application No. 63/412,322, entitled “ASSEMBLY OF AN INTEGRATED CIRCUIT IN A CHIP SCALE BALL GRID ARRAY,” filed Sep. 30, 2022, which is hereby incorporated by reference as if set forth in full in this application for all purposes.

### BACKGROUND

A ball grid array (BGA) is a type of surface-mount packaging that is used for integrated circuits. BGA packages are used to permanently mount devices such as microprocessors onto a motherboard. A BGA can provide more interconnection pins than can be put on a dual in-line or flat package. Conventional BGAs typically use a small printed circuit board (PCB) substrate to route solder balls to bond pads of integrated circuits (ICs) within the BGA.

### SUMMARY

Implementations generally relate to an assembly of an integrated circuit (IC) in a chip scale ball grid array. In some implementations, an assembly includes an integrated circuit chip having wire bond pads. The assembly further includes ball bumps coupled to the wire bond pads of the IC chip. The assembly further includes an overmold that encapsulates the IC chip. The assembly further includes ball contact pads coupled to the overmold, where the ball contact pads are electrically coupled to the wire bond pads by way of the ball bumps. The assembly further includes solder balls coupled to the ball contact pads.

With further regard to the assembly, in some implementations, the assembly further includes vias in the overmold that couple to the ball bumps on the IC chip. In some implementations, the assembly further includes vias in the overmold that couple to the ball bumps on the IC chip; and trace lines between ball contact pads to the vias of the IC chip. In some implementations, the assembly further includes vias in the overmold that couple to the ball bumps on the IC chip; and conductive material that fills the vias. In some implementations, where the overmold has a sufficiently thin dimension so as to expose at least a portion of the ball bumps on the IC chip. In some implementations, the assembly further includes trace lines that couple the ball contact pads to the ball bumps on the IC chip. In some implementations, the IC chip is built into an array of IC chips.

In some implementations, a system includes one or more processors, and includes logic encoded in one or more non-transitory computer-readable storage media for execution by the one or more processors. When executed, the logic is operable to cause the one or more processors to perform operations including applying ball bumps to wire bond pads of an IC chip; encapsulating the IC chip with an overmold; building ball contact pads on the overmold, where the ball contact pads are electrically coupled to the wire bond pads by way of the ball bumps; and applying solder balls to the ball contact pads.

With further regard to the system, in some implementations, the logic when executed is further operable to cause the one or more processors to perform operations including drilling vias in the overmold to the ball bumps on the IC chip. In some implementations, the logic when executed is further operable to cause the one or more processors to perform operations including: drilling vias in the overmold to the ball bumps on the IC chip; and drawing trace lines from the ball contact pads to the vias of the IC chip. In some implementations, the logic when executed is further operable to cause the one or more processors to perform operations including: drilling vias in the overmold to the ball bumps on the IC chip; and filling the vias with a conductive material. In some implementations, the overmold has a sufficiently thin dimension so as to expose at least a portion of the ball bumps on the IC chip. In some implementations, the logic when executed is further operable to cause the one or more processors to perform operations including drawing trace lines from the ball contact pads to the ball bumps on the IC chip. In some implementations, the logic when executed is further operable to cause the one or more processors to perform operations including performing a singulation process on an assembly containing the IC chip, wherein the assembly is built into an array of assemblies.

In some implementations, a computer-implemented method includes: applying ball bumps to wire bond pads of an IC chip. The method further includes encapsulating the IC chip with an overmold. The method further includes building ball contact pads on the overmold, where the ball contact pads are electrically coupled to the wire bond pads by way of the ball bumps. The method further includes applying solder balls to the ball contact pads.

With further regard to the method, in some implementations, the method further includes drilling vias in the overmold to the ball bumps on the IC chip. In some implementations, the method further includes: drilling vias in the overmold to the ball bumps on the IC chip; and drawing trace lines from the ball contact pads to the vias of the IC chip. In some implementations, the method further includes: drilling vias in the overmold to the ball bumps on the IC chip; and filling the vias with a conductive material. In some implementations, the overmold has a sufficiently thin dimension so as to expose at least a portion of the ball bumps on the IC chip. In some implementations, the method further includes drawing trace lines from the ball contact pads to the ball bumps on the IC chip.

A further understanding of the nature and the advantages of particular implementations disclosed herein may be realized by reference of the remaining portions of the specification and the attached drawings.

### BRIEF DESCRIPTION OF THE DRAWINGS

FIG. 1 is a block diagram of an example assembly of an integrated circuit (IC) in a chip scale ball grid array (CSP BGA), which may be used for some implementations described herein.

FIG. 2 is an example flow diagram for building an assembly of an IC in a CSP BGA, according to some implementations.

FIG. 3 is a block diagram of IC chip to which ball bumps are applied, according to some implementations.

FIG. 4 is a perspective-view of a portion of an IC chip where ball bumps are applied to wire bond pads, according to some implementations.

FIG. 5 is a perspective-view diagram of an IC chip assembly that includes an IC chip that is encapsulated with an overmold, according to some implementations.

FIG. 6 is a side-view diagram of an example portion of a chip assembly having a via in an overmold, according to some implementations.

FIG. 7 is a top-view diagram of an IC chip assembly having an IC chip encapsulated in an overmold, where trace lines are drawn on the overmold, according to some implementations.

FIG. 8 is a top-view diagram of an example BGA assembly 800, according to some implementations.

FIG. 9 is a block diagram of an example computer system, which may be used for some implementations described herein.

### DETAILED DESCRIPTION

Implementations described herein relate to an assembly of an integrated circuit (IC) in a chip scale ball grid array (CSP BGA). Implementations described herein utilize a mold compound as a dielectric layer of a BGA assembly instead of a printed circuit board (PCB) substrate. The system connects to wire bond pads of the IC using laser-drilled vias. The system routes top-surface trace lines from the vias to ball pads and ultimately to solder balls to efficiently build a CSP BGA assembly or package.

As described in more detail herein, in various implementations, an assembly includes an IC chip having wire bond pads. The assembly further includes ball bumps coupled to the wire bond pads of the IC chip. The assembly further includes an overmold that encapsulates the IC chip. In some implementations, the assembly optionally has vias that extend to the ball bumps on the IC chip. In some implementations, the assembly optionally as an overmold that is sufficiently thin such that the at least a portion of the ball bumps are exposed. A thin overmold eliminates the need for vias. The assembly further includes ball contact pads coupled to the overmold, where the ball contact pads are electrically coupled to the wire bond pads by way of the ball bumps. In some implementations, the assembly may optionally have trace lines that connect the ball contact pads to the ball bumps. The assembly further includes solder balls coupled to the ball contact pads. As a result, implementations provide a BGA package or flip chip that can be attached to a motherboard.

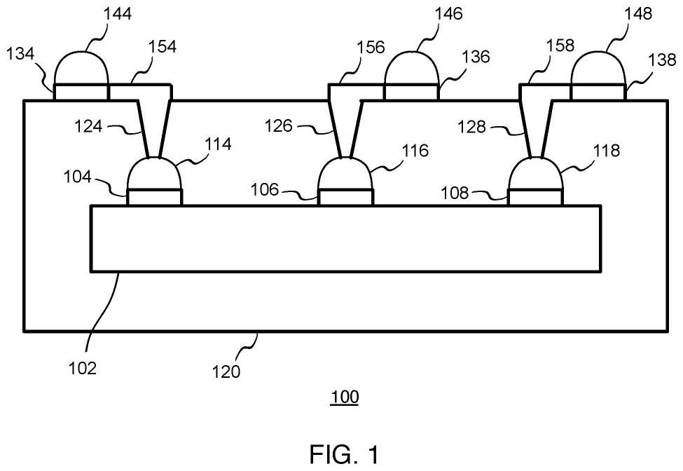

FIG. 1 is a block diagram of an example assembly 100 of an integrated circuit (IC) in a chip scale ball grid array (CSP BGA), which may be used for some implementations described herein. As shown, assembly 100 includes an IC chip 102 having wire bond pads 104, 106, and 108. Assembly 100 further includes ball bumps 114, 116, and 118 coupled to wire bond pads 104, 106, and 108 of IC chip 102. Assembly 100 further includes an overmold 120 that encapsulates IC chip 102.

In various implementations, assembly 100 further includes vias 124, 126, and 128 coupled to ball bumps 114, 116, and 118, respectively. Assembly 100 further includes ball contact pads 134, 136, and 138 coupled to overmold 120, where ball contact pads 134, 136, and 138 are electrically coupled to wire bond pads 104, 106, and 108 by way of ball bumps 114, 116, and 118. Assembly 100 further includes solder balls 144, 146, and 148 coupled to ball contact pads 134, 136, and 138, respectively. In various implementations, assembly 100 further includes trace lines 154, 156, and 158 that couple between ball contact pads 134, 136, and 138 and ball bumps 114, 116, and 118, respectively.

For ease of illustration, three sets of wire bond pads, ball bumps, vias, trace lines, ball contact pads, and solder balls are shown. There may be any number of such sets, depending on the particular implementation. Example implementations directed to the building of an assembly such as assembly 100 and operations thereof are described in more detail below. The resulting assembly that is built may be referred to an IC assembly, an IC chip assembly, a ball grid array (BGA), a BGA assembly, a BGA package, chip scale ball grid array (CSP BGA), a redistributed layer (RDL) BGA, or a flip chip.

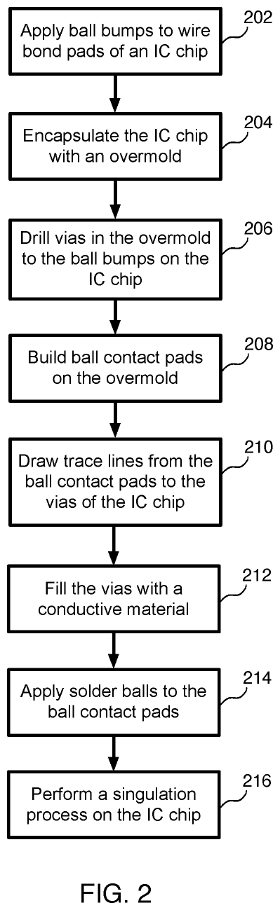

FIG. 2 is an example flow diagram for building an assembly of an IC in a CSP BGA, according to some implementations. In various implementations, a method is initiated at block 202, where a system applies ball bumps to wire bond pads of an IC chip. The system applies the gold ball bumps in order to protect the IC chip's wire bond pads during subsequent lasering of vias. More specifically, in various implementations, the ball bumps function as laser stops, which prevent damage to the thin wire bond pads under the ball bumps.

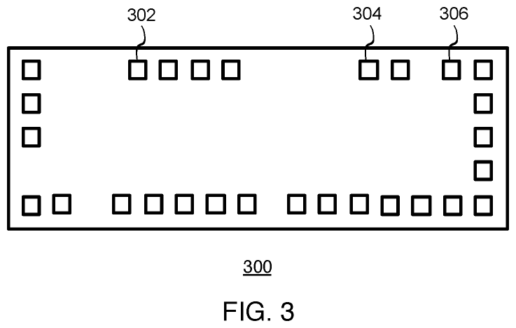

FIG. 3 is a block diagram of IC chip 300 to which ball bumps are applied, according to some implementations. In various implementations, a system receives IC chip 300 for building an assembly of an IC in a CSP BGA. At this stage in the process, IC chip 300 is bare in that is it not protected. As shown, IC chip 300 includes wire bond pads such as wire bond pads 302, 304, 306, etc. The other squares shown also represent wire bond pads but are not numbered for ease of illustration. In various implementations, the system may determine locations of the wire bond pads using a preexisting IC circuit design stored in a computer aided design (CAD) file. The system may use the determined locations, for example, to place elements such as ball bumps, vias, etc., implementations of which are described in more detail herein.

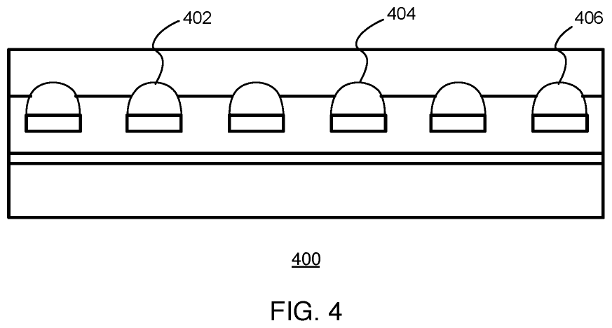

FIG. 4 is a perspective-view of a portion of an IC chip 400 where ball bumps such as ball bumps 402, 404, and 406 are applied to wire bond pads, according to some implementations. The system applies a ball bump to each wire bond pad. In various implementations, the system applies gold ball bumps. Gold ball bumps may be referred to as wire bond gold ball or stud bumps. As indicated herein, the ball bumps function as laser stops, which prevent damage to the thin wire bond pads under the ball bumps.

Referring still to FIG. 2, at block 204, the system encapsulates the IC chip with an overmold. In various implementations, the system encapsulates or molds over the IC with a molding compound. The encapsulation process results in an encapsulated IC having a solid overmold.

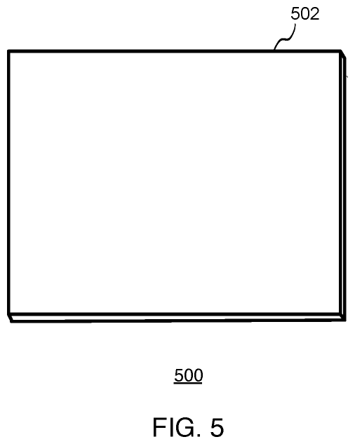

FIG. 5 is a perspective-view diagram of an IC chip assembly 500 that includes an IC chip (not shown) that is encapsulated with an overmold 502, according to some implementations. In various implementations, overmold 502 may be an overmold compound that is made of a thermoset epoxy material. An overmold may also be referred to as a mold casing or an encapsulant.

At block 206 of FIG. 2, the system drills vias in the overmold to the ball bumps on the IC chip. In various implementations, the system drills the vias to the gold ball bumps for subsequent electrical contact with wire bond pads by way of the gold ball bumps. The system may use any suitable technology such as a laser processing system or other means such as jetting for drawing the traces.

In various implementations, the lasering process exposes binders in the overmold. For example, metalorganic binders are integrated into the overmold and released when the overmold is lasered. When heated, these binders enable copper ions to adhere or bond to these binders in the overmold, thereby making copper traces. In some implementations, copper traces may be made without using any special mold compound (e.g., with no binders). For example, a jet printer may be used to print the conductor traces to connect from the ball bump and draw traces emanating from the bond pad. As such, implementations may involve either laser-etch traces or jetted trace lines.

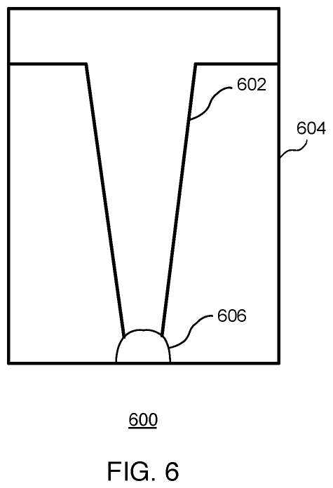

FIG. 6 is a side-view diagram of an example portion of a chip assembly 600 having a via 602 in an overmold 604, according to some implementations. As shown, the system drills vias such as via 602 through overmold 604. For ease of illustration, only one via is shown. There may be any number of vias depending on the implementation. In various implementations, the vias extend toward the IC's wire bond pads (not shown) in order to enable electrical connections to the IC's wire bond pads. As indicated above the vias may enable electrical connections to the IC's wire bond pads indirectly by way of ball bumps such as ball bump 606. In various implementations, the system may utilize any suitable laser process system to drill the vias.

In some implementations, the system may omit the vias by using a thin layer of overmold, where the overmold has a sufficiently thin dimension so as to expose at least a portion of the ball bumps on the IC chip. Exposure of the ball bumps may be created by controlling mold thickness such that a thinner overmold results. Alternatively, the system may use a laser to slightly expose the ball bumps if not already partially exposed. These techniques enable the system to draw trace lines to connect the ball bumps to solder balls. Example implementations directed to solder balls are described in more detail below.

Referring again to FIG. 2, at block 208, the system builds ball contact pads on the overmold, where the ball contact pads are electrically coupled to the wire bond pads through vias and by way of ball bumps. As indicated above, the vias provide electrical connections to wire bond pads or nodes in the IC circuitry, where the wire bond pads are hidden underneath the encapsulant due to the encapsulation process.

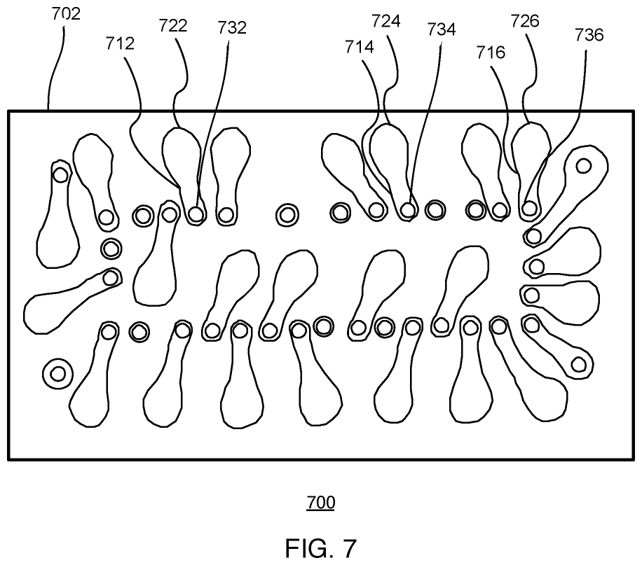

FIG. 7 is a top-view diagram of an IC chip assembly 700 having an IC chip (not shown) encapsulated in an overmold 702, where trace lines such as trace lines 712, 714, and 716 are drawn on overmold 702, according to some implementations. As shown, trace lines 712, 714, and 716 extend from ball contact pads such as ball contact pads 722, 724, and 726 to corresponding vias such as vias 732, 734, and 736. The system may use any suitable laser process system or other means such as jetting to draw the trace lines onto the overmold.

As shown, ball contact pads 722, 724, and 726 are built on the outer surface of overmold 702. As such, overmold 702 functions as a dielectric in the assembly and obviates the need for a substrate. Ball contact pads 722, 724, and 726 are where the system places and attaches solder balls, which are described below. In various implementations, the ball contact pads provide electrical connections between the wire bond pads and electrical nodes or terminals of a motherboard by way of the solder balls attached to the ball contact pads. The ball contact pads may also be referred to as ball grid array (BGA) contact pads or land grid array (LGA) contact pads.

At block 210 of FIG. 2, the system draws trace lines from ball contact pads to the vias of the IC chip, as shown in the example implementation of FIG. 7. In various implementations, the trace lines are configured to provide electrical connection between ball contact pads 722, 724, and 726 and wire bond pads (not shown) through vias 732, 734, and 736 and by way of the ball bumps (not shown).

In various implementations, the system may draw the trace lines with gold. This enables copper to be placed over and adhere to the gold. While some example implementations are described herein in the context of gold trace lines, these implementations may also apply to silver ink. The system may use any suitable ink jet process system to apply the silver ink, or copper ink, or other conductor materials.

In some implementations, the system may draw trace lines from the ball contact pads to the ball bumps on the IC chip. This alternative implementation is an option if the vias are not needed. For example, the vias are not be needed and used in scenarios where the overmold is thin enough to expose the ball bumps on the wire bond pads of the IC chip.

Because the system places the trace lines directly onto the mold casing, the system obviates a need for a separate printed circuit board (PCB) routing substrate. Conventional BGAs are typically attached to a small PCB substrate Eliminating the need for a PCB substrate saves on costs and materials associated with a PCB substrate, which is beneficial to the overall assembly and process. Furthermore, eliminating the need for a PCB substrate enables a lighter chip with thinner dimensions, as a PCB substrate would add 0.05 mm to 0.20 mm or more to the package thickness.

In step 212 of FIG. 2, the system fills the vias with a conductive material. The system fills the vias with the conductive material in order to extend electrical conduction from the wire bond pads or gold ball bumps underneath the encapsulant to the opposite end of the vias at the outer surface of the encapsulant.

In some implementations, the system may fill the vias with a conductive ink. To apply the conductive ink, the system may dip or soak the overmolded IC chip in a conductive ink solution. The particular type of conductive ink may vary, depending on the implementation. For example, in some implementations, the conductive ink may be silver. In some implementations, the system may fill the vias with electroless plating. To apply the electroless plating, the system may dip or soak the overmolded IC chip in an electroless copper-rich solution to plate copper lines.

In various implementations, the trace lines that extend from the vias to their corresponding ball pads are subsequently covered by copper. This is performed by the system dipping the overmolded IC chip in an electroless copper solution, where the copper adheres to the gold trace lines. This results in copper lines that extend from the wire bond pads or gold ball bumps underneath the encapsulant to the target ball pads. Some implementations may use jet filling of ink for traces instead lasering to reduce moisture risk at the vias.

In step 214 of FIG. 2, the system applies solder balls to the ball contact pads. Adding the solder balls to the ball contact pads results in a BGA package assembly.

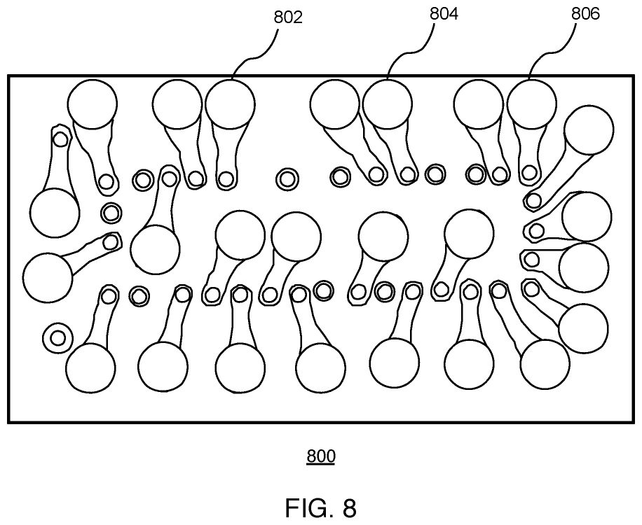

FIG. 8 is a top-view diagram of an example BGA assembly 800, according to some implementations. As shown, BGA assembly 800 has a BGA package footprint. As shown, BGA assembly includes solder balls such as solder balls 802, 804, and 806 that are applied to ball contact pads.

In some implementations, the system may dispense or stencil print a non-conductive insulating liquid or apply film over vias and traces for protection. The protective coating plugs any existing via holes, which prevents moisture from going down vias holes and making contact with the integrated circuit. The system leaves the solder balls free of such protection in order to maintain their conductivity.

In various scenarios, plating over the copper lines could oxidize. In some implementations, to protect from oxidation, the system may apply a protective coating (e.g., nickel, palladium, gold, etc.) in order to make the chip more reliable and averse to corrosion. In some implementations, if the system uses a silver ink in lieu of copper, the system may apply another type of coating to protect the silver.

Referring again to FIG. 2, in step 216, the system performs a singulation process on the IC chip assembly, according to some implementations. In various scenarios, the BGA assembly shown in FIG. 8 is itself a part of an array of BGA assemblies that are to be separated from each other.

In various implementations, the system may build the BGA chip assembly in an array or panel of BGA chip assemblies, where the panel includes X and Y rows/columns of BGA assemblies for efficiency and cost reduction. In various implementations, the system cuts the BGA assemblies to singulate them in gang fashion in an efficient process. In various implementations, the system applies a cutting or sawing process that separates the BGA assemblies into individual separated BGA assemblies. Each resulting IC chip assembly has a BGA package footprint. Once completed, the CSP BGA assembly may be attached to a motherboard.

Although the steps, operations, or computations may be presented in a specific order, the order may be changed in particular implementations. Other orderings of the steps are possible, depending on the particular implementation. In some particular implementations, multiple steps shown as sequential in this specification may be performed at the same time. Also, some implementations may not have all of the steps shown and/or may have other steps instead of, or in addition to, those shown herein.

Implementations described herein provide various benefits. For example, implementations do not need a PCB substrate, as traces are made directly onto the mold casing, which saves on costs and materials Eliminating the need for a PCB substrate enables thinner dimensions, as a PCB substrate would add 100 um or more to the package thickness.

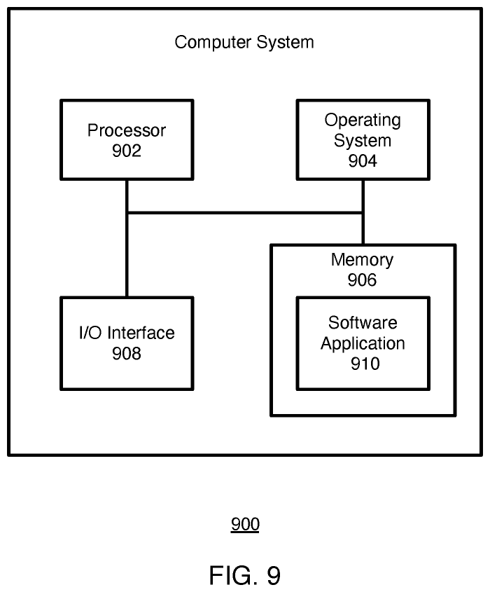

FIG. 9 is a block diagram of an example computer system 900, which may be used for some implementations described herein. For example, computer system 900 may be used to perform implementations described herein. In some implementations, computer system 900 may include a processor 902, an operating system 904, a memory 906, and an input/output (I/O) interface 908. In various implementations, processor 902 may be used to implement various functions and features described herein, as well as to perform the method implementations described herein. While processor 902 is described as performing implementations described herein, any suitable component or combination of components of computer system 900 or any suitable processor or processors associated with computer system 900 or any suitable system may perform the steps described. Implementations described herein may be carried out on a user device, on a server, or a combination of both.

Computer system 900 also includes a software application 910, which may be stored on memory 906 or on any other suitable storage location or computer-readable medium. Software application 910 provides instructions that enable processor 902 to perform the implementations described herein and other functions. Software application may also include an engine such as a network engine for performing various functions associated with one or more networks and network communications. The components of computer system 900 may be implemented by one or more processors or any combination of hardware devices, as well as any combination of hardware, software, firmware, etc.

For ease of illustration, FIG. 9 shows one block for each of processor 902, operating system 904, memory 906, I/O interface 908, and software application 910. These blocks 902, 904, 906, 908, and 910 may represent multiple processors, operating systems, memories, I/O interfaces, and software applications. In various implementations, computer system 900 may not have all of the components shown and/or may have other elements including other types of components instead of, or in addition to, those shown herein.

Although the description has been described with respect to particular implementations thereof, these particular implementations are merely illustrative, and not restrictive. Concepts illustrated in the examples may be applied to other examples and implementations.

In various implementations, software is encoded in one or more non-transitory computer-readable media for execution by one or more processors. The software when executed by one or more processors is operable to perform the implementations described herein and other functions.

Any suitable programming language can be used to implement the routines of particular implementations including C, C++, C #, Java, JavaScript, assembly language, etc. Different programming techniques can be employed such as procedural or object oriented. The routines can execute on a single processing device or multiple processors. Although the steps, operations, or computations may be presented in a specific order, this order may be changed in different particular implementations. In some particular implementations, multiple steps shown as sequential in this specification can be performed at the same time.

Particular implementations may be implemented in a non-transitory computer-readable storage medium (also referred to as a machine-readable storage medium) for use by or in connection with the instruction execution system, apparatus, or device. Particular implementations can be implemented in the form of control logic in software or hardware or a combination of both. The control logic when executed by one or more processors is operable to perform the implementations described herein and other functions. For example, a tangible medium such as a hardware storage device can be used to store the control logic, which can include executable instructions.

Particular implementations may be implemented by using a programmable general purpose digital computer, and/or by using application specific integrated circuits, programmable logic devices, field programmable gate arrays, optical, chemical, biological, quantum or nanoengineered systems, components and mechanisms. In general, the functions of particular implementations can be achieved by any means as is known in the art. Distributed, networked systems, components, and/or circuits can be used. Communication, or transfer, of data may be wired, wireless, or by any other means.

A “processor” may include any suitable hardware and/or software system, mechanism, or component that processes data, signals or other information. A processor may include a system with a general-purpose central processing unit, multiple processing units, dedicated circuitry for achieving functionality, or other systems. Processing need not be limited to a geographic location, or have temporal limitations. For example, a processor may perform its functions in “real-time,” “offline,” in a “batch mode,” etc. Portions of processing may be performed at different times and at different locations, by different (or the same) processing systems. A computer may be any processor in communication with a memory. The memory may be any suitable data storage, memory and/or non-transitory computer-readable storage medium, including electronic storage devices such as random-access memory (RAM), read-only memory (ROM), magnetic storage device (hard disk drive or the like), flash, optical storage device (CD, DVD or the like), magnetic or optical disk, or other tangible media suitable for storing instructions (e.g., program or software instructions) for execution by the processor. For example, a tangible medium such as a hardware storage device can be used to store the control logic, which can include executable instructions. The instructions can also be contained in, and provided as, an electronic signal, for example in the form of software as a service (SaaS) delivered from a server (e.g., a distributed system and/or a cloud computing system).

It will also be appreciated that one or more of the elements depicted in the drawings/figures can also be implemented in a more separated or integrated manner, or even removed or rendered as inoperable in certain cases, as is useful in accordance with a particular application. It is also within the spirit and scope to implement a program or code that can be stored in a machine-readable medium to permit a computer to perform any of the methods described above.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

Thus, while particular implementations have been described herein, latitudes of modification, various changes, and substitutions are intended in the foregoing disclosures, and it will be appreciated that in some instances some features of particular implementations will be employed without a corresponding use of other features without departing from the scope and spirit as set forth. Therefore, many modifications may be made to adapt a particular situation or material to the essential scope and spirit.

What is claimed is:

1. An assembly comprises:
an integrated circuit (IC) chip having wire bond pads;
ball bumps coupled to the wire bond pads of the IC chip;
an overmold that encapsulates the IC chip;
ball contact pads coupled to the overmold, wherein the ball contact pads are electrically coupled to the wire bond pads by way of the ball bumps; and
solder balls coupled to the ball contact pads.

2. The assembly of claim 1, further comprising vias in the overmold that couple to the ball bumps on the IC chip.

3. The assembly of claim 1, further comprising:
vias in the overmold that couple to the ball bumps on the IC chip; and
trace lines between ball contact pads to the vias of the IC chip.

4. The assembly of claim 1, further comprising
vias in the overmold that couple to the ball bumps on the IC chip; and
conductive material that fills the vias.

5. The assembly of claim 1, wherein the overmold has a sufficiently thin dimension so as to expose at least a portion of the ball bumps on the IC chip.

6. The assembly of claim 1, further comprising trace lines that couple the ball contact pads to the ball bumps on the IC chip.

7. The assembly of claim 1, wherein the assembly is built into an array of assemblies.

8. A system comprising:
one or more processors; and
logic encoded in one or more non-transitory computer-readable storage media for execution by the one or more processors and when executed operable to cause the one or more processors to perform operations comprising:
applying ball bumps to wire bond pads of an integrated circuit (IC) chip;
encapsulating the IC chip with an overmold;
building ball contact pads on the overmold, wherein the ball contact pads are electrically coupled to the wire bond pads by way of the ball bumps; and
applying solder balls to the ball contact pads.

9. The system of claim 8, wherein the logic when executed is further operable to cause the one or more processors to perform operations comprising drilling vias in the overmold to the ball bumps on the IC chip.

10. The system of claim 8, wherein the logic when executed is further operable to cause the one or more processors to perform operations comprising:
drilling vias in the overmold to the ball bumps on the IC chip; and
drawing trace lines from the ball contact pads to the vias of the IC chip.

11. The system of claim 8, wherein the logic when executed is further operable to cause the one or more processors to perform operations comprising:
drilling vias in the overmold to the ball bumps on the IC chip; and
filling the vias with a conductive material.

12. The system of claim 8, wherein the overmold has a sufficiently thin dimension so as to expose at least a portion of the ball bumps on the IC chip.

13. The system of claim 8, wherein the logic when executed is further operable to cause the one or more processors to perform operations comprising drawing trace lines from the ball contact pads to the ball bumps on the IC chip.

14. The system of claim 8, wherein the logic when executed is further operable to cause the one or more processors to perform operations comprising performing a singulation process on an assembly containing the IC chip, wherein the assembly is built into an array of assemblies.

15. A computer-implemented method comprising:
applying ball bumps to wire bond pads of an integrated circuit (IC) chip;
encapsulating the IC chip with an overmold;
building ball contact pads on the overmold, wherein the ball contact pads are electrically coupled to the wire bond pads by way of the ball bumps; and
applying solder balls to the ball contact pads.

16. The method of claim 15, further comprising drilling vias in the overmold to the ball bumps on the IC chip.

17. The method of claim 15, further comprising:
drilling vias in the overmold to the ball bumps on the IC chip; and
drawing trace lines from the ball contact pads to the vias of the IC chip.

18. The method of claim 15, further comprising:
drilling vias in the overmold to the ball bumps on the IC chip; and
filling the vias with a conductive material.

19. The method of claim 15, wherein the overmold has a sufficiently thin dimension so as to expose at least a portion of the ball bumps on the IC chip.

20. The method of claim 15, further comprising drawing trace lines from the ball contact pads to the ball bumps on the IC chip.
